(19) United States
(12) Patent Application Publication
(10) Pub. No.: US 2009/0057856 A1
(43) Pub. Date: Mar. 5, 2009

(54) BONDING-PATTERNED DEVICE AND ELECTRONIC COMPONENT

(75) Inventor: Satoshi Komoto, Fukuoka-ken (JP)

Correspondence Address: AMIN, TUROCY & CALVIN, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/201,212

(22) Filed: Aug. 29, 2008

(30) Foreign Application Priority Data
Aug. 30, 2007 (JP) 2007-224167

(51) Int. Cl. H01L 23/13

(52) U.S. Cl. 257/676; 257/E23.004

(57) ABSTRACT

A bonding-patterned device comprises: a bonding layer provided on a bonding surface to be bonded to a mounting member. The bonding-patterned device has a planar shape which is generally a parallelogram. The bonding-patterned device is separated and cut out from a plate material along a plurality of evenly spaced straight lines, the surface of the plate material provided with the bonding layer being partitioned into a plurality of compartments by a plurality of evenly spaced straight lines parallel to each of the two pairs of opposite sides of the generally parallelogram shape. The plurality of compartments are classified into first compartments and second compartments alternately arranged in a checkerboard configuration, where the bonding layer is provided inside the first compartments, and the bonding layer is not provided in the second compartments and on the contours thereof. x=2nα and y=(2m−1)β, or y=2nβ and x=(2m−1)α where x and y are the lengths of the two pairs of opposite sides of the generally parallelogram shape, α and β are the lengths of two pairs of opposite sides of the compartment parallel to said x and y, respectively, and n and m are natural numbers, planar shapes of each bonding layer provided inside each of the first compartments are congruent each other, and locations of each bonding layer in each of the first compartment are identical.

### CROSS-REFERENCE TO RELATED APPLICATIONS

This application is based upon and claims the benefit of priority from the prior Japanese Patent Application No. 2007-224167, filed on Aug. 30, 2007; the entire contents of which are incorporated herein by reference.

### BACKGROUND OF THE INVENTION

1. Field of the Invention

This invention relates to a bonding-patterned device and an electronic components

2. Background Art

Electronic components with semiconductor devices or electronic parts bonded onto a mounting member such as a substrate or lead frame are widely used.

For example, in the case of a surface-mounted electronic component with semiconductor device chips bonded onto a lead frame, if torsional distortion occurs in the lead frame, an external force such as a torsional stress is applied to the bonding surface between the chip and the lead frame, and the chip may detach from the lead frame. To prevent detachment due to torsional stress, reduction of the bonding area is effective. However, reduction of the bonding area causes the problem of decreased strength against shear stress.

### SUMMARY OF THE INVENTION

According to an aspect of the invention, there is provided a bonding-patterned device including: a bonding layer provided on a bonding surface to be bonded to a mounting member, the bonding-patterned device having a planar shape which is generally a parallelogram, the bonding-patterned device being separated and cut out from a plate material along a plurality of evenly spaced straight lines, the surface of the plate material provided with the bonding layer being partitioned into a plurality of compartments by a plurality of evenly spaced straight lines parallel to each of the two pairs of opposite sides of the generally parallelogram shape, the plurality of compartments being classified into first compartments and second compartments alternately arranged in a checkerboard configuration, where the bonding layer is provided inside the first compartments, and the bonding layer is not provided in the second compartments and on the contours thereof, x=2nα and y=(2m−1)β, or y=2nβ and x=(2m−1)α where x and y are the lengths of the two pairs of opposite sides of the generally parallelogram shape, α and β are the lengths of two pairs of opposite sides of the compartment parallel to said x and y, respectively, and n and m are natural numbers, planar shapes of each bonding layer provided inside each of the first compartments are congruent each other, and locations of each bonding layer in each of the first compartment are identical.

According to another aspect of the invention, there is provided an electronic component including: a mounting member; and a bonding-patterned device bonded onto the mounting member, the bonding-patterned device including: a bonding layer provided on a bonding surface to be bonded to a mounting member, the bonding-patterned device having a planar shape which is generally a parallelogram, the bonding-patterned device being separated and cut out from a plate material along a plurality of evenly spaced straight lines, the surface of the plate material provided with the bonding layer being partitioned into a plurality of compartments by a plurality of evenly spaced straight lines parallel to each of the two pairs of opposite sides of the generally parallelogram shape, the plurality of compartments being classified into first compartments and second compartments alternately arranged in a checkerboard configuration, where the bonding layer is provided inside the first compartments, and the bonding layer is not provided in the second compartments and on the contours thereof, x=2nα and y=(2m−1)β, or y=2nβ and x=(2m−1)α where x and y are the lengths of the two pairs of opposite sides of the generally parallelogram shape, α and β are the lengths of two pairs of opposite sides of the compartment parallel to said x and y, respectively, and n and m are natural numbers, planar shapes of each bonding layer provided inside each of the first compartments are congruent each other, and locations of each bonding layer in each of the first compartment are Identical.

According to another aspect of the invention, there is provided an electronic component Including: a mounting member; a bonding layer provided on the mounting member; and a bonding-patterned device having a planar shape which is generally a parallelogram and bonded to the mounting member via the bonding layer, the surface of the mounting member provided with the bonding layer being partitioned into a plurality of compartments by a plurality of evenly spaced straight lines parallel to each of the two pairs of opposite sides of the generally parallelogram shape, the plurality of compartments being classified into first compartments and second compartments alternately arranged in a checkerboard configuration, where the bonding layer is provided inside the first compartments, and the bonding layer is not provided In the second compartments and on the contours thereof, x=2nα and y=(2m−1)β, or y=2nβ and x=(2m−1)α where x and y are the lengths of the two pairs of opposite sides of the generally parallelogram shape, α and β are the lengths of two pairs of opposite sides of the compartment parallel to said x and y, respectively, and n and m are natural numbers, and planar shapes of each bonding layer provided inside each of the first compartments are congruent each other, and locations of each bonding layer in each of the first compartment are identical.

### BRIEF DESCRIPTION OF THE DRAWINGS

FIGS. 1A and 1B are schematic views showing a bonding patterned device according to this embodiment;

FIGS. 2A and 2B are schematic views showing a bonding patterned device according to this embodiment;

FIGS. 3A and 3B are schematic views showing a bonding patterned device according to this embodiment;

FIGS. 4A to 4C are conceptual views showing how the bonding-patterned device shown in FIGS. 1A to 3B is cut out from a wafer;

FIGS. 5A and 5B are schematic views showing a bonding-patterned device of a comparative example;

FIGS. 6A to 6E are schematic views for describing the corner number;

FIG. 7 is a schematic view illustrating the pattern shape of the bonding layer 16;

FIG. 8 is a schematic view illustrating the pattern shape of the bonding layer 16;

FIG. 9 is a schematic view illustrating the pattern shape of the bonding layer 16;

FIGS. 10A and 10B are schematic views showing an electronic component according to this embodiment; and

FIG. 11 is a schematic view showing a second example of the electronic component of this embodiment.

### DETAILED DESCRIPTION OF THE INVENTION

An embodiment of the invention will now be described with reference to the drawings.

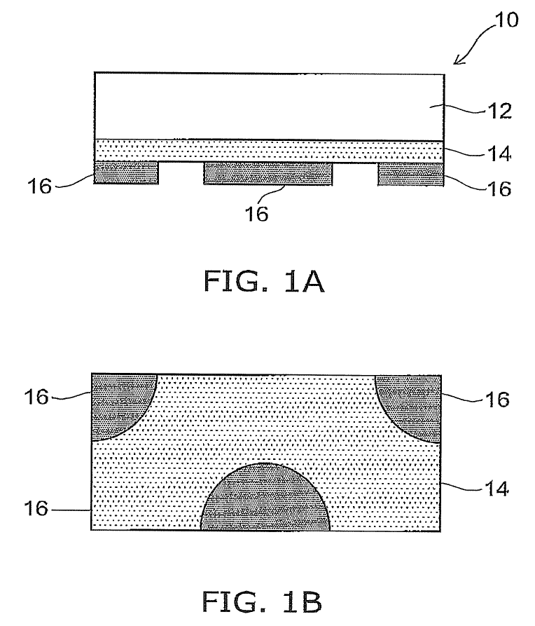

FIGS. 1 to 3 show bonding-patterned devices according to this embodiment, in which FIGS. 1A, 2A, and 3A are schematic front views, and FIGS. 1B, 2B, and 3B are schematic bottom views. In FIG. 1 and the subsequent figures, the same elements as those in the earlier figures are labeled with like reference numerals, and the detailed description thereof is omitted.

As described later in detail with reference to examples, the bonding-patterned devices shown in FIGS. 1 to 3 encompass various devices, including, for example, optical devices such as light receiving and light emitting devices, electronic devices such as transistors and diodes, and mounting devices such as submounts. For example, in the case where the bonding-patterned device (the device provided with a bonding pattern) 10 is a light receiving device, it includes a semiconductor layer 12, an electrode 14 provided on its backside, and a bonding layer 16 provided on the surface of the electrode 14. The semiconductor layer 12 suitably includes such layers as an optoelectric conversion layer and a semiconductor substrate, not shown. The electrode 14 serves as an anode or cathode electrode of the light receiving device. The bonding layer 16 can be formed from solder, a metal bump, or an adhesive (such as silver paste) containing conductive material.

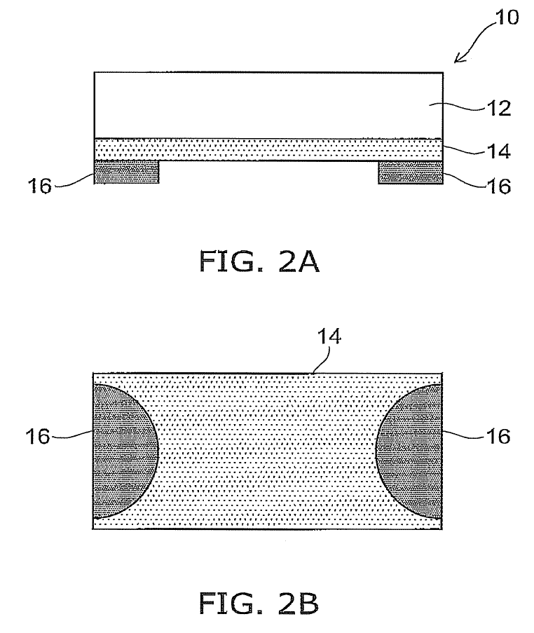

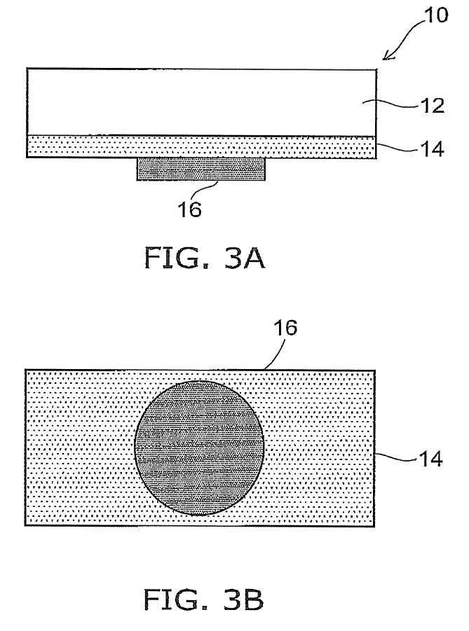

In the bonding-patterned device 10 shown in FIG. 1, bonding layers 16 are provided at three locations in total, i.e., at the upper left and right corner and near the center of the lower long side, as viewed from the bottom side of the device (FIG. 1B). In the bonding-patterned device 10 shown in FIG. 2, bonding layers 16 are provided at two locations in total, i.e., on both the left and right short side, as viewed from the bottom side of the device (FIG. 2B). In the bonding-patterned device 10 shown in FIG. 3, a bonding layer 16 is provided at only one location, i.e., near the center, as viewed from the bottom side of the device (FIG. 3B).

The area ratio of the bonding layers 16 to the bottom surface of the device 10 is generally the same for all the bonding-patterned devices shown in FIGS. 1 to 3. For example, the total area of the bonding layers 16 can be approximately 30 percent of the area of the bottom surface of the device 10 for all the bonding-patterned devices of FIGS. 1 to 3.

According to this embodiment, any of the bonding-patterned devices shown in FIGS. 1 to 3 can be cut out from the same wafer (plate material). In any of these cases, when the device is bonded to a mounting member such as a lead frame, a peel strength at a mechanically high level can be maintained by allowing the peel strength against shear stress (die shear stress) to be compatible with the peel strength against the torsion of the lead frame.

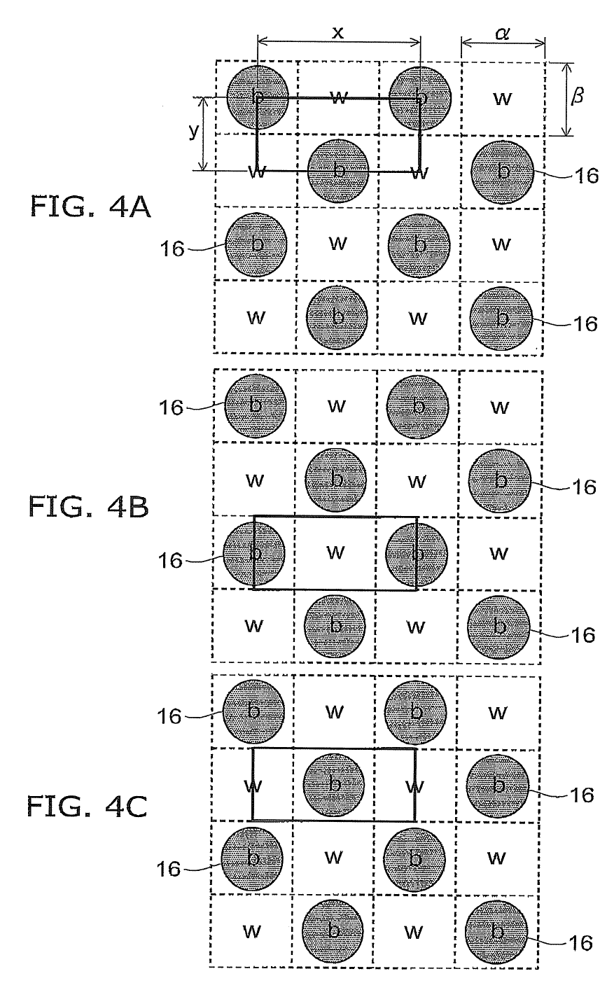

FIG. 4 is a conceptual view showing how the bonding-patterned device shown in FIGS. 1 to 3 is cut out from a wafer.

Bonding layers 16 are formed in a checkerboard configuration on the surface of the wafer. As shown in FIG. 4A, when the bonding-patterned device 10 is cut out so as to include three of the bonding layers 16, the bonding-patterned device shown in FIG. 1 is obtained. On the other hand, as shown in FIG. 4B, when the bonding-patterned device 10 is cut out so as to include two of the bonding layers 16, the bonding-patterned device 10 shown in FIG. 2 is obtained. Furthermore, as shown in FIG. 4C, when the bonding-patterned device 10 is cut out so as to include only one bonding layer 16, the bonding-patterned device 10 shown in FIG. 3 is obtained.

Here, in any example of FIGS. 1 to 3, the pattern of the bonding layers 16 on the bonding-patterned device 10 can be replicated and two-dimensionally juxtaposed adjacent to each other to obtain the layout of the bonding layers 16 in the original wafer.

In the following, the layout of the bonding layers 16 and the function and effect thereof in this embodiment are described in detail.

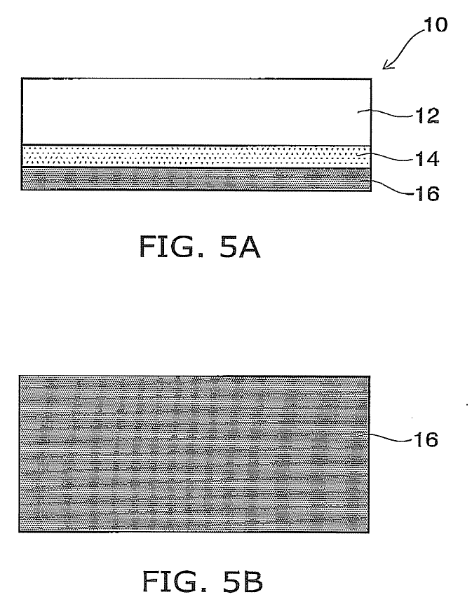

FIG. 5 is a schematic view showing a bonding-patterned device of a comparative example.

In this comparative example, a bonding layer 16 is uniformly provided throughout the backside of the bonding-patterned device. This bonding-patterned device, bonded onto a lead frame, has a sufficient bonding strength in the peel test (die shear test) in which a shear stress parallel to the bonding surface is directly applied to the device. However, when an external force such as a torsional stress due to torsional distortion in the lead frame is applied to the bonding surface, the bonding-patterned device may detach from the lead frame with a relatively small force. One effective method for preventing detachment due to torsional stress is reduction of the bonding area. However, excessive reduction of the bonding area decreases bonding strength against shear stress.

In this regard, according to this embodiment, the bonding layer 16 is patterned, and a particular condition is imposed on the arrangement of the pattern. Thus, this embodiment provides a bonding-patterned member being easy to manufacture and allowing the strength against shear stress to be compatible with the strength against torsional stress.

Here, if any location corresponding to a corner of the device as viewed from its backside is populated with a bonding layer 16, the number of corners populated with the bonding layers 16, out of the four corners of the device, is defined as the “corner number”.

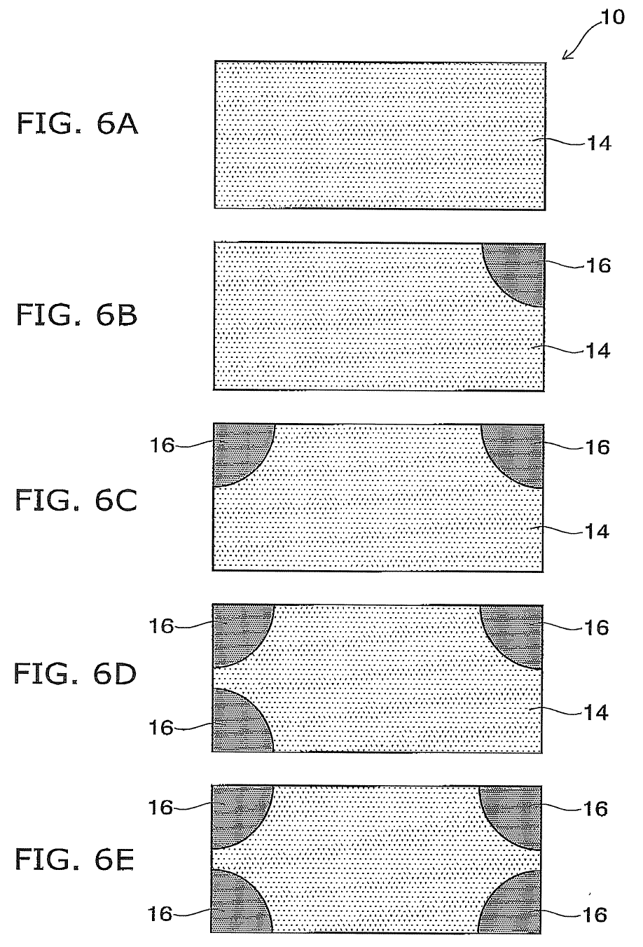

FIG. 6 is a schematic view for describing the corner number.

More specifically, FIG. 6A shows the case where none of the four corners of the device is populated with a bonding layer 16. The corner number in this case is 0 (zero). However, this also includes the case where a bonding layer 16 is provided at a location other than the four corners of the device. That is, corner number 0 also includes the case where a bonding layer 16 is provided on any side other than the four corners or anywhere on the backside away from such corners and sides.

FIG. 6B shows the case where only one of the four corners of the device is populated with a bonding layer 16. The corner number in this case is 1. Again, this also includes the case where a bonding layer 16 is provided at a location other than the four corners of the device. That is, corner number 1 also includes the case where a bonding layer 16 is provided on any side other than the four corners or anywhere on the backside away from such corners and sides.

FIG. 6C shows the case where two of the four corners of the device are populated with bonding layers 16. The corner number in this case is 2. As described above with reference to FIGS. 6A and 6B, this also includes the case where a bonding layer 16 is provided at a location other than the four corners of the device.

FIG. 6D shows the case where three of the four corners of the device are populated with bonding layers 16. The corner number in this case is 3. Again, as described above with reference to FIGS. 6A and 68, this also includes the case where a bonding layer 16 is provided at a location other than the four corners of the device.

FIG. 6E shows the case where all the four corners of the device are populated with bonding layers 16. The corner number in this case is 4. Again, as described above with reference to FIGS. 6A and 6B, this also includes the case where a bonding layer 16 is provided at a location other than the four corners of the device.

The following summarizes the peel strength for these bonding-patterned devices bonded to a mounting member.

TABLE 1

Mechanical strength

| | Peel strength against | Peel strength against |
|---|---|---|
| Solder pattern | shear stress | torsional distortion |
| Area ratio | Positive correlation | Negative correlation |
| (0-100%) | | |
| Corner number | No correlation | Negative correlation |
| (0-4) | | |

The peel strength of the bonding-patterned device against shear stress (die shear strength) is positively correlated with the ratio of the area of the bonding layers 16 to the area of the mounting surface of the bonding-patterned device. That is, as the area ratio of the bonding layers 16 increases, the peel strength against shear stress is improved. However, the peel strength against torsional stress due to the torsion of the mounting member is negatively correlated with the area ratio of the bonding layers 16. That is, as the area ratio of the bonding layers increases, the peel strength against torsional stress tends to decrease.

On the other hand, with regard to the relation of the peel strength to the corner number in the case where the area ratio of the bonding layers 16 is kept constant, no significant correlation is found in the peel strength against shear stress. However, the peel strength against torsional stress is negatively correlated with the corner number.

TABLE 2 summarizes an example of the result of examining the relationship between the peel strength against torsional stress and the corner number in the case where the area ratio of the bonding layers 16 is kept constant.

TABLE 2

| Corner number | 0 | 1 | 2 | 3 | 4 |
|---|---|---|---|---|---|
| Strength against | 10.2 | 8.9 | 7.3 | 6.7 | 5.3 |
| torsional distortion | | | | | |

Here, the bonding-patterned device is mounted on a lead frame, and a torsional stress is applied to both ends of the lead frame. TABLE 2 lists the torque of the torsional stress (in N·cm, newton-centimeters) observed when the bonding-patterned device is peeled.

It turns out from TABLE 2 that, in the case where the area ratio of the bonding layers 16 is kept constant, it is desirable to minimize the corner number of the bonding layers 16. This is presumably because peeling in response to torsional stress is related to the distance between the points of application of force.

It turns out from the foregoing results that both the peel strength against shear stress and the peel strength against torsional stress can be increased by suitably setting the area ratio of the bonding layers 16 and then minimizing the corner number. In the simplest case, this condition can be satisfied by forming a bonding layer 16 with a suitable area near the center of the backside of the bonding-patterned device 10 (i.e., corner number 0).

However, to this end, it is necessary to align the bonding layers 16 with the bonding-patterned device 10. Typically, bonding-patterned devices such as photodiodes are cut out from a wafer with reference to the pattern on the frontside of the wafer. Hence, in this case, the bonding layers 16 on the backside need to be formed in alignment with the frontside pattern of the wafer. However, such alignment of the bonding layers 16 is complicated and likely to cause increased manufacturing cost and yield decrease.

In contrast, this embodiment does not need to align the bonding layers 16 with the pattern on the frontside of the wafer, and can ensure a prescribed peel strength wherever the bonding layers 16 are formed on the bonding-patterned device 10.

More specifically, this embodiment is based on the condition such that the corner number is allowed to be 0 to 2 and that the area ratio of the bonding layers 16 does not depend on the position of the pattern. This condition is as described below.

First, as shown in FIG. 4, the bonding-patterned device 10 with the planar shape being generally a parallelogram is separated and cut out from a plate material (wafer) along a plurality of evenly spaced straight lines. In this case, the surface of the plate material (wafer) provided with the bonding layers 16 is partitioned into a plurality of compartments by a plurality of evenly spaced straight lines parallel to each of the two pairs of opposite sides of the generally parallelogram shape of the bonding-patterned device 10. Furthermore, the plurality of compartments are classified into first compartments b and second compartments w alternately arranged in a checkerboard configuration. The bonding layers 16 are provided inside the first compartments b, and not provided In the second compartments w and on the contours thereof (the first compartments b and the second compartments w can be reversed).

Then, it is required that the following formulas be satisfied:

x=2nα and y=(2m−1)β, or

y=2nβ and x=(2m−1)α

where x, y, α, and β are shown in FIG. 4. Specifically, x and y are the vertical and horizontal length of the bonding-patterned device 10, α and β are the vertical and horizontal length of the compartment in which the bonding layer 16 is formed, and n and m are natural numbers. FIG. 4 illustrates the case of n=m=1.

More specifically, α and β are the vertical and horizontal length of an imaginary lattice formed on the wafer surface as shown in FIG. 4, where the side of length x is parallel to the side of length a, and the side of length y is parallel to the side of length p. The bonding layers 16 are formed in a checkerboard configuration so that the bonding layers. 16 are not formed in adjacent ones of such compartments. Here, the size of the bonding layer 16 needs to be smaller than a and P. That is, the ratio of the area of the bonding layers 16 to the surface area of the wafer has an allowable range of greater than 0% and less than 50%. Planar shapes of each bonding layer 16 provided inside each of the first compartments b are congruent each other, and locations of each bonding layer 16 in each of the first compartments b are Identical

Then, as shown in FIGS. 1 to 4, from whichever position of the wafer the bonding-patterned device 10 is cut out, the corner number can be limited within the range of 0 to 2. Consequently, as seen from TABLE 2, the decrease of the peel strength against torsional stress occurring for a corner number of 3 or 4, for example, can be prevented. More specifically, the peel strength against torsional stress is 6.7 for a corner number of 3, and decreases to 5.3 for a corner number of 4. However, according to this embodiment, the strength is 7.3 at lowest (corner number=2), and 10.2 at best (corner number=0).

Furthermore, this embodiment does not need to align the bonding layers 16 with the pattern on the frontside of the wafer. That is, a prescribed mechanical strength can be ensured without complicating the manufacturing process.

In this embodiment, as long as the above condition is satisfied, the shape of the bonding layer 16 is arbitrary in principle, and the area ratio can be set so that the peel strength against shear stress is reconciled with the peel strength against torsional stress.

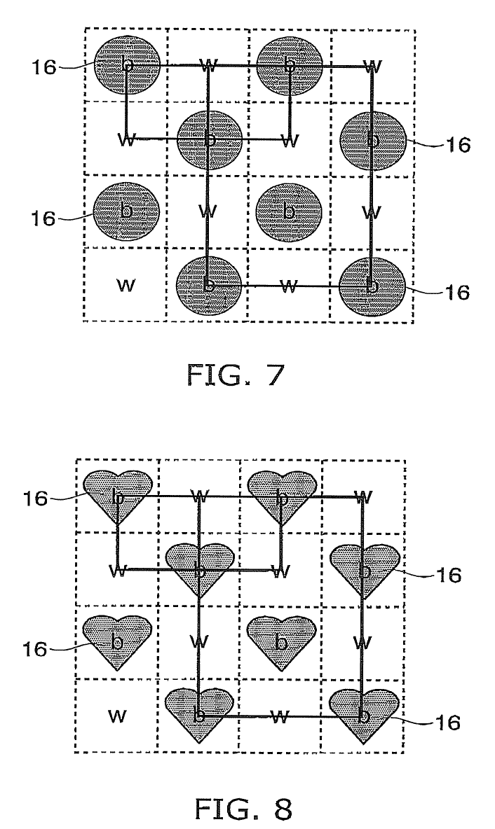

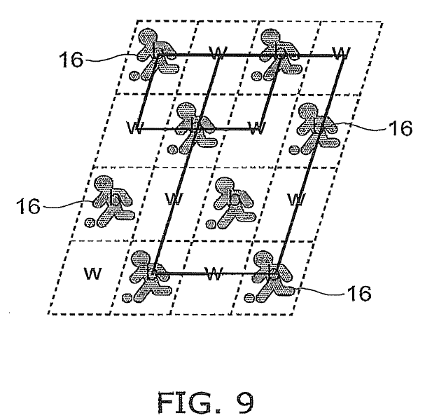

FIGS. 7 to 9 are schematic views illustrating the pattern shape of the bonding layer 16. More specifically, as shown in FIG. 7, the bonding layer 16 can have a generally circular shape. Alternatively, it can have an axisymmetric shape as Illustrated in FIG. 8, or an asymmetric shape as illustrated in FIG. 9.

Furthermore, FIGS. 7 to 9 illustrate the outline of the bonding-patterned device by thick solid lines. However, the outline can be located anywhere else. That is, as long as the above condition is satisfied, from whichever position of the wafer the bonding-patterned device is cut out, the corner number for the bonding layers 16 can be limited within the range of 0 to 2.

Moreover, FIGS. 7 to 9 each show the case of n=m=1 and the case of n=1, m=2. As n or m increases, the points of application of force are dispersed because the number of bonding layers 16 formed in the bonding-patterned device increases. Accordingly, the difference of the peel strength against torsional stress between the case of the corner number limited within the range of 0 to 2 and the case of the corner number being 3 or 4 tends to decrease. That is, this embodiment is more effective for smaller n and m, and achieves the most significant effect in the case of n=m=1.

With regard to the hardness of the bonding layer 16, as far as the peel strength of the bonding-patterned device against torsional stress applied to the mounting member is concerned, the peel strength tends to be high as the hardness of the bonding layer 16 becomes lower.

In the following, examples of the electronic component according to this embodiment are described

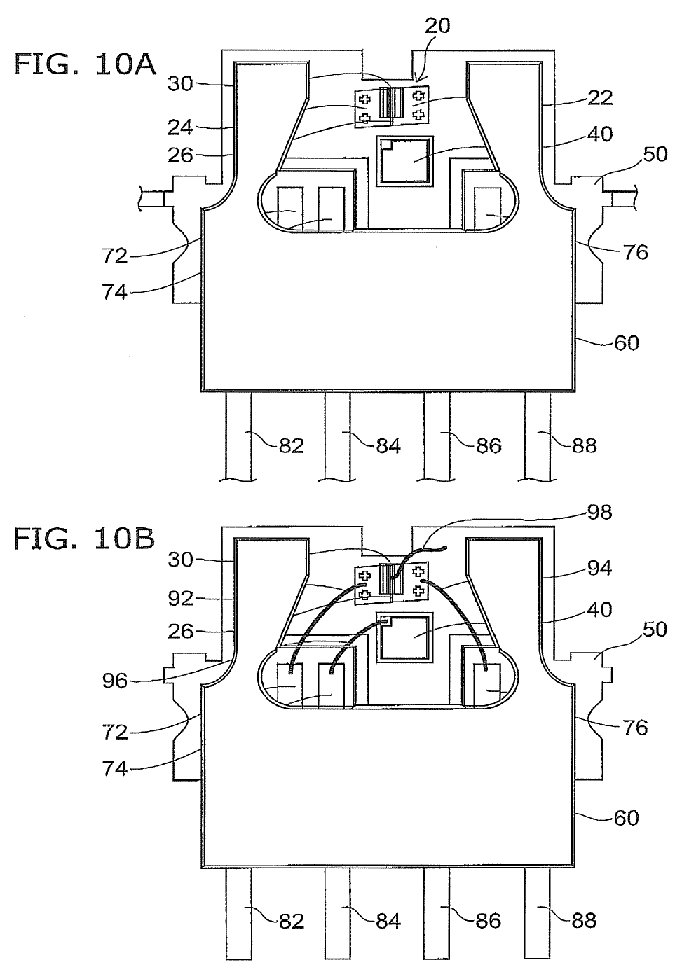

FIG. 10 is a schematic view showing an electronic component according to this embodiment.

This example shows a two-wavelength semiconductor laser apparatus. FIGS. 10A and 10B are schematic views showing the internal structure of the semiconductor laser apparatus during assembly.

A submount (bonding-patterned device) 20 and a light receiving device (bonding-patterned device) 40 are bonded onto a lead frame 50 molded with a molding resin 60. The submount 20 and the light receiving device 40 have bonding layers, not shown, on the bonding surface with the lead frame 50. The bonding layers have the layout satisfying the condition according to this embodiment as described above.

Here, the submount 20 has a structure in which the surface of a ceramic is covered with a metal. Two electrode patterns 22, 24 electrically isolated from each other by an isolation groove 26 are provided on the surface of the submount 20. A two-wavelength semiconductor laser device 30 is mounted on the submount 20. The semiconductor laser device 30 includes two resonators emitting laser light at two different wavelengths. Electrodes corresponding to each of these resonators are formed on the mounting surface of the semiconductor laser device 30, and are electrically connected to the electrode patterns 22, 24 of the submount 20. The light receiving device 40 can be used to monitor the intensity of laser light emitted from the semiconductor laser device 30.

In this semiconductor laser apparatus, the component mounting portion for the submount 20 and the light receiving device 40 is not sealed with sealing resin, but left as a hollow structure. In the case of the hollow structure, the mounted components such as the submount 20 are mechanically fixed to the apparatus only by the bonding surface with the lead frame 50. Hence, as compared with the dense structure in which the mounted components are sealed with filling resin, the mounted components such as the submount 20 and the light receiving device 40 are likely to detach from the lead frame 50, and the lead frame 50 is also susceptible to distortion. In contrast, by bonding the submount 20 and the light receiving device 40 using the bonding layers 16 according to this embodiment, peeling from the lead frame 50 can be reliably and easily prevented.

The process for manufacturing a semiconductor laser apparatus according to this embodiment is now described.

First, a lead frame 50 is pressed and formed into a desired pattern, and a molding resin 60 to serve as an envelope is molded on the lead frame 50 by injection molding or the like so as to surround the device mounting portion. The base material of the lead frame 50 can be a copper-based material in view of heat dissipation during operation. Alternatively, in some cases, it is also possible to use an iron-based material such as 42 alloy. In view of assemblability, the lead frame 50 can be provided with a suitable cladding of gold, nickel, or palladium plating.

Next, a submount 20 and a light receiving device 40 are bonded onto the molded lead frame 50. The light receiving device 40 is cut out in a rectangular or square shape from a silicon wafer, with its backside being patterned with bonding layers of gold-tin solder or the like according to this embodiment. The submount 20 is cut out in a parallelogram shape from a ceramic wafer, with its backside being patterned with bonding layers of gold-tin solder or the like according to this embodiment.

The area ratio of these bonding layers can be set to approximately 30 to 40%. For example, a metallic mask, which is micropatterned beforehand by photolithography, is closely attached onto a wafer surface, and solder is evaporated thereon. Thus, the bonding layers 16 can be patterned. Here, close contact with the wafer can be ensured by sequentially overlaying the wafer and a magnetic mask on a magnetized holding jig to use the magnetic attraction between the holding jig and the mask.

Other methods for forming bonding layers 16 illustratively include the method of uniformly evaporating solder on a wafer beforehand and patterning the solder by photolithography, and the method of patterning a resist on a wafer beforehand by photolithography, then evaporating solder, and peeling it by lift-off. Further alternatively, relatively thick electrodes are patterned on a wafer surface beforehand by photolithography to form a desired projection-depression pattern, and a solder layer is uniformly formed thereon so that only the projected portion of the structure abuts the lead frame at the time of bonding.

In practice, in view of vignetting due to mask thickness and the infiltration of etchant, simple and large bonding layers 16 are more favorable to transferability. In any case, because this embodiment does not need to align the wafer with the pattern, the process can be easily implemented. The submount 20 and the light receiving device 40 can be bonded to the lead frame 50 by heat-melting the backside bonding layers 16 to approximately 300° C. It is also possible to use silver epoxy adhesive and the like instead of solder.

A semiconductor laser device 30 is bonded onto the submount 20. The submount 20 can be made of aluminum nitride, which has a linear expansion coefficient similar to that of the semiconductor laser device 30 and has higher thermal conductivity than silicon and the like. The semiconductor laser device 30 can be mounted illustratively by heat-melt bonding the bonding layers of gold-tin solder to approximately 300° C. to ensure electrical conduction. It is also possible to use silver epoxy adhesive and the like instead of solder.

The semiconductor laser device 30 is a monolithic, two-wavelength semiconductor laser device emitting both infrared and visible light. However, alternatively, it can be a single-wavelength semiconductor laser device emitting only infrared light, only visible light, or only ultraviolet light. It is also possible to mount a plurality of semiconductor laser devices.

As shown in FIG. 10B, the mounted components are electrically wired to leads 72, 76, 74 by gold wires 92, 94, 96, respectively. Furthermore, the common electrode of the semiconductor laser device 30 is wired to the lead frame 50 by a wire 98.

Subsequently, a resin or metallic lid is attached and fixed to the molded lead frame, which is separated by lead cutting. Thus, a semiconductor laser apparatus is completed. The leads 82, 84, 86, 88 are connected to the semiconductor laser device 30 (backside electrode), the light receiving device 40 (frontside electrode), the semiconductor laser device 30 (backside electrode), and the semiconductor laser device 30 (frontside electrode), respectively.

According to this embodiment, even in the case where the semiconductor laser apparatus being pressed into an optical pickup head casing, for example, is subjected to a large external force, no trouble such as chip peeling occurs in the semiconductor laser apparatus.

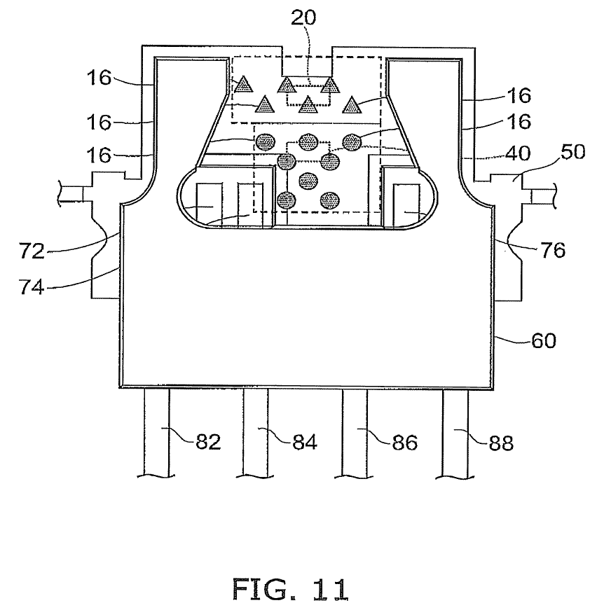

FIG. 11 is a schematic view showing a second example of the electronic component of this embodiment.

This example is different in that the bonding layers 16 are formed on the lead frame 50 side, rather than the mounted components (the submount 20 and the light receiving device 40) side. In this case, the corner number can be limited within the range of 0 to 2 independent of the mounting position of the mounted components. That is, the peel strength against shear stress and the peel strength against torsional stress can be ensured without the need for high accuracy to mount the mounted components. Also in this example, as described above with reference to FIGS. 7 to 9, the most significant effect can be achieved in the case of n=m=1,

In the case where silver epoxy or cream solder is used for the bonding layers 16, a mask, which is micropatterned beforehand by photolithography, is closely attached onto the surface of the lead frame 50, and stamping or the like can be used for patterning on the device mounting surface. Alternatively, the bonding layers 16 can be patterned beforehand on another base material and transferred onto the lead frame 50, or a nozzle, which is processed beforehand in conformity with the pattern, can be closely attached to the lead frame 50 to apply bonding layers 16 by injection. Further alternatively, the same effect is achieved also by forming a desired projection-depression pattern on the surface of the lead frame 50 by press working, and uniformly and thinly applying an adhesive onto the pattern so that only the projected portion of the structure serves as a bonding layer 16 to abut the mounted components (the submount 20 and the light receiving device 40) at the time of bonding.

The submount 20 and the light receiving device 40 are bonded onto the bonding layers 16 thus formed. In the case of mounted components ranging over a plurality of types, a pattern of bonding layers 16 can be formed at a mounting position for each type. Alternatively, depending on the shape and size of the submount 20 and the light receiving device 40, these can be mounted on the bonding layers 16 having the same pattern. The bonding layers 16 serving as an adhesive can be cured as needed by heating, drying, or ultraviolet irradiation. In any case, because this embodiment does not need the technique for aligning the lead frame 50 with the pattern or the technique for mounting components with high accuracy, the process can be easily implemented.

While FIGS. 10 and 11 illustrate a semiconductor laser apparatus, this embodiment is basically applicable to any electronic components in which a device is bonded to a mounting member. The bonding layer 16 can be insulative if electrical conduction is not needed. Furthermore, this embodiment is also applicable to bonding components onto a deformable object such as a flexible substrate. Moreover, this embodiment is also widely applicable to any purposes of bonding components, such as structures having bonding capability like planar fasteners, and structures using adsorption or attraction based on vacuum, magnetism, and electrostatic force.

The embodiment of the invention has been described with reference to the examples. However, the invention is not limited to these examples. That is, the examples can be modified by those skilled in the art, and such modifications are also encompassed within the scope of the invention as long as they do not depart from the spirit of the invention.

The pattern of the bonding layers provided on the bonding-patterned device of this embodiment can be replicated and two-dimensionally juxtaposed adjacent to each other to obtain the layout of the bonding layers in the original wafer or other plate material from which the bonding-patterned device is cut out.

1. A bonding-patterned device comprising:
a bonding layer provided on a bonding surface to be bonded to a mounting member,
the bonding-patterned device having a planar shape which is generally a parallelogram,
the bonding-patterned device being separated and cut out from a plate material along a plurality of evenly spaced straight lines,
the surface of the plate material provided with the bonding layer being partitioned into a plurality of compartments by a plurality of evenly spaced straight lines parallel to each of the two pairs of opposite sides of the generally parallelogram shape, the plurality of compartments being classified into first compartments and second compartments alternately arranged In a checkerboard configuration, where
the bonding layer is selectively provided inside the first compartments, and
the bonding layer is not provided in the second compartments and on the contours thereof,
x=2nα and y=(2m−1)β, or
y=2nβ and x=(2m−1)α
where x and y are the lengths of the two pairs of opposite sides of the generally parallelogram shape, α and β are the lengths of two pairs of opposite sides of the compartment parallel to said x and y, respectively, and n and m are natural numbers,
planar shapes of each bonding layer provided inside each of the first compartments are congruent each other, and
locations of each bonding layer in each of the first compartments are identical.

2. The bonding-patterned device according to claim 1, wherein said n is 1, and said m is 1.

3. The bonding-patterned device according to claim 1, wherein the plate material has an electrode provided under the bonding layer, the electrode covering entire surface of the first compartments and the second compartments.

4. The bonding-patterned device according to claim 1 wherein the parallelogram is a rectangular.

5. The bonding-patterned device according to claim 1, wherein planar shape of the selectively provided bonding layer is symmetric.

6. The bonding-patterned device according to claim 1, wherein planar shape of the selectively provided bonding layer is asymmetric.

7. An electronic component comprising:
a mounting member; and
a bonding-patterned device bonded onto the mounting member,
the bonding-patterned device including:
a bonding layer provided on a bonding surface to be bonded to a mounting member,
the bonding-patterned device having a planar shape which is generally a parallelogram,
the bonding-patterned device being separated and cut out from a plate material along a plurality of evenly spaced straight lines,
the surface of the plate material provided with the bonding layer being partitioned into a plurality of compartments by a plurality of evenly spaced straight lines parallel to each of the two pairs of opposite sides of the generally parallelogram shape, the plurality of compartments being classified into first compartments and second compartments alternately arranged in a checkerboard configuration, where
the bonding layer is selectively provided inside the first compartments,
the bonding layer is not provided in the second compartments and on the contours thereof, and
x=2nα and y=(2m−1)β, or
y=2nβ and x=(2m−1)α
where x and y are the lengths of the two pairs of opposite sides of the generally parallelogram shape, α and β are the lengths of two pairs of opposite sides of the compartment parallel to said x and y, respectively, and n and m are natural numbers,
planar shapes of each bonding layer provided inside each of the first compartments are congruent each other, and
locations of each bonding layer in each of the first compartments are identical

8. The electronic component according to claim 7, wherein said n is 1, and said m is 1.

9. The electronic component according to claim 7, wherein the plate material has an electrode provided under the bonding layer, the electrode covering entire surface of the first compartments and the second compartments.

10. The electronic component according to claim 7, wherein planar shape of the selectively provided bonding layer is symmetric.

11. The electronic component according to claim 7, wherein planar shape of the selectively provided bonding layer is asymmetric.

12. The electronic component according to claim 7, having a hollow structure, where the wherein the bonding-patterned device is not sealed.

13. The electronic component according to claim 7, wherein the bonding-patterned device is a submount having a ceramic covered with a metal,
the electric component further comprising a semiconductor laser which is provided on the submount.

14. An electronic component comprising:
a mounting member;
a bonding layer provided on the mounting member; and
a bonding-patterned device having a planar shape which is generally a parallelogram and bonded to the mounting member via the bonding layer,
the surface of the mounting member provided with the bonding layer being partitioned into a plurality of compartments by a plurality of evenly spaced straight lines parallel to each of the two pairs of opposite sides of the generally parallelogram shape, the plurality of compartments being classified into first compartments and second compartments alternately arranged In a checkerboard configuration, where
the bonding layer is selectively provided inside the first compartments, and
the bonding layer is not provided in the second compartments and on the contours thereof,
x=2nα and y=(2m−1)β, or
y=2nβ and x=(2m−1)α
where x and y are the lengths of the two pairs of opposite sides of the generally parallelogram shape, α and β are the lengths of two pairs of opposite sides of the compartment parallel to said x and y, respectively, and n and m are natural numbers,
planar shapes of each bonding layer provided inside each of the first compartments are congruent each other, and
locations of each bonding layer In each of the first compartments are identical.

15. The electronic component according to claim 14, wherein said n is 1, and said m is 1.

16. The electronic component according to claim 14, wherein the plate material has an electrode provided under the bonding layer, the electrode covering entire surface of the first compartments and the second compartments.

17. The electronic component according to claim 14, wherein planar shape of the selectively provided bonding layer is symmetric.

18. The electronic component according to claim 14, Wherein planar shape of the selectively provided bonding layer is asymmetric.

19. The electronic component according to claim 15, having a hollow structure, where the wherein the bonding-patterned device is not sealed.

20. The electronic component according to claim 15, wherein the bonding-patterned device is a submount having a ceramic covered with a metal,
the electric component further comprising a semiconductor laser which is provided on the submount.
